(19) United States
(12) Patent Application Publication
(10) Pub. No.: US 2025/0272812 A1
(43) Pub. Date: Aug. 28, 2025

(54) SIDE-BY-SIDE OFF-CENTER DIE OVERLAY TARGET

(71) Applicant: KLA Corporation, Milpitas, CA (US)

(72) Inventors: Eitan Hajaj, Ashqelon (IL); Roie Volkovich, Hadera (IL)

(21) Appl. No.: 18/587,703

(22) Filed: Feb. 26, 2024

(51) Int. Cl. G06T 7/00; G06T 7/13; G06T 7/60

(52) U.S. Cl. CPC G06T 7/0002; G06T 7/13; G06T 7/60; G06T 2207/30148; G06T 2207/30204

(57) ABSTRACT

An overlay metrology system and method are disclosed. The overlay metrology system may include a detector and a controller. The controller may be configured to execute program instructions causing the processors to acquire an image of an overlay target of a sample. The sample may include one or more dies corresponding to one or more substrates. The overlay target may include one or more measurement regions, each corresponding to a die. Each measurement region may include one or more die marks located on the dies and substrate marks located on the substrates. The processors may be configured to determine a plurality of overlay measurements based on the image.

### TECHNICAL FIELD

The present disclosure relates generally to overlay metrology and, more particularly, to overlay metrology of stacked substrates using side-by-side overlay targets.

### BACKGROUND

Overlay metrology refers to measurements of the relative alignment of layers on a sample such as, but not limited to, semiconductor devices. An overlay measurement, or a measurement of overlay error, typically refers to a measurement of the misalignment of fabricated features on two or more sample layers. Overlay may include the misalignment of features between different substrates, such as die alignment of dies stacked onto another substrate. Proper alignment is necessary for proper functioning of the device.

Demands to decrease feature size and increase feature density are resulting in correspondingly increased demand for accurate and efficient overlay metrology. Metrology systems typically determine metrology data associated with a sample by measuring or otherwise inspecting dedicated metrology targets (i.e., overlay targets) distributed across the sample. Accordingly, the sample is typically mounted on a translation stage and translated such that the metrology targets are sequentially moved into a measurement field of view.

### SUMMARY

An overlay target configured for stacked substrates is disclosed in accordance with one or more illustrative embodiments of the present disclosure. In one illustrative embodiment, the overlay target may include one or more measurement regions, each corresponding to a die. In another illustrative embodiment, each measurement region may include one or more die marks located on one or more dies. In another illustrative embodiment, the measurement regions may include substrate marks located on one or more substrates, where the substrate marks are unobstructed by the dies. In another illustrative embodiment, the substrate marks may include a first direction substrate mark aligned along a first direction relative to a die mark. In another illustrative embodiment, the substrate marks may include a second direction substrate mark aligned along a second direction relative to the die mark, where the second direction is different from the first direction.

In a further aspect, the substrate marks of each measurement region may further include an acquisition mark, where the acquisition mark is aligned along the first direction relative to the second direction substrate mark, and aligned along the second direction relative to the first direction substrate mark. In another illustrative embodiment, the one or more measurement regions may include two or more measurement regions corresponding to two or more dies, where at least one substrate mark of each measurement region is commonly shared between multiple measurement regions. In another illustrative embodiment, the two or more measurement regions may include four or more measurement regions corresponding to four or more dies. In another illustrative embodiment, the at least one substrate mark of each measurement region that is commonly shared between multiple measurement regions may include the acquisition mark, the first direction substrate mark, and the second direction substrate mark.

In a further aspect, the overlay target may include a three by three grid of marks configured for four dies in a two by two arrangement with space between each die for the substrate marks. In another illustrative embodiment, the center mark of the three by three grid of marks may comprise the acquisition mark and may be configured to be commonly shared between the four or more measurement regions corresponding to the four dies. In another illustrative embodiment, each corner of the three by three grid of marks may comprise a respective die mark of a respective die of the four or more dies.

In a further aspect, the overlay target may be configured to be contained within a single field of view having a width and a height no greater than 2000 microns. In another illustrative embodiment, the overlay target may be configured to be contained within a single field of view having a width no greater than 600 microns. In another illustrative embodiment, the die mark of the die may comprise a see-through mark including die structures of the die that are above substrate structures of the one or more substrates. In another illustrative embodiment, the overlay target may include at least one of an advance imaging metrology (AIM) style target, or a box in box style target.

An overlay metrology system is disclosed in accordance with one or more illustrative embodiments of the present disclosure. In one illustrative embodiment, the overlay metrology system may include a detector. In another illustrative embodiment, the system may include a controller communicatively coupled to the detector. The controller may include one or more processors configured to execute program instructions. In another illustrative embodiment, the program instructions may cause the processors to acquire an image of an overlay target of a sample. The sample may include one or more dies corresponding to one or more substrates. In another illustrative embodiment, the overlay target may include one or more measurement regions, each measurement region corresponding to a die. In another illustrative embodiment, each measurement region may include one or more die marks located on the dies. In another illustrative embodiment, the measurement regions may include substrate marks located on the substrates, where the substrate marks are unobstructed by the dies. In another illustrative embodiment, the substrate marks may include a first direction substrate mark aligned along a first direction relative to a die mark. In another illustrative embodiment, the substrate marks may include a second direction substrate mark aligned along a second direction relative to the die mark, where the second direction is different than the first direction. In another illustrative embodiment, the program instructions may cause the processors to determine a plurality of overlay measurements based on the image corresponding to the one or more measurement regions and the one or more dies.

An overlay metrology system is disclosed in accordance with one or more illustrative embodiments of the present disclosure. In one illustrative embodiment, the overlay metrology system may include an optical subsystem. In another illustrative embodiment, the system may include a controller. The controller may include one or more processors configured to execute program instructions. In another illustrative embodiment, the program instructions may cause the one or more processors to acquire an image emanating from an overlay target of a sample. In another illustrative embodiment, the image may include one or more measurement regions. In another illustrative embodiment, the sample may include one or more dies corresponding to one or more substrates. In another illustrative embodiment, the overlay target may include the one or more measurement regions, each measurement region corresponding to a die. In another illustrative embodiment, each measurement region may include substrate marks located on a substrate, unobstructed by the one or more dies. In another illustrative embodiment, the substrate marks may include a first direction substrate mark offset along a first direction relative to a first die edge. In another illustrative embodiment, the substrate marks may include a second direction substrate mark offset along a second direction relative to a second die edge, where the second direction is different than the first direction. In another illustrative embodiment, the controller may determine, based on the image, a plurality of overlay measurements corresponding to the one or more measurement regions and the one or more dies.

A method is disclosed in accordance with one or more illustrative embodiments of the present disclosure. In one illustrative embodiment, the method may include acquiring an image of an overlay target of a sample. In another illustrative embodiment, the image may include one or more measurement regions. In another illustrative embodiment, the sample may include one or more dies corresponding to one or more substrates. In another illustrative embodiment, the overlay target may include the one or more measurement regions, each measurement region corresponding to a die. In another illustrative embodiment, each measurement region may include one or more die marks located on one or more dies. In another illustrative embodiment, the measurement regions may include substrate marks located on the one or more substrates, where the substrate marks are unobstructed by the one or more dies. In another illustrative embodiment, the substrate marks may include a first direction substrate mark aligned along a first direction relative to a die mark. In another illustrative embodiment, the substrate marks may include a second direction substrate mark aligned along a second direction relative to the die mark, where the second direction is different than the first direction. In another illustrative embodiment, the method may include determining, based on the image, a plurality of overlay measurements corresponding to the one or more measurement regions and the one or more dies.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF THE DRAWINGS

The numerous advantages of the disclosure may be better understood by those skilled in the art by reference to the accompanying figures.

FIG. 1A illustrates a conceptual view of a system for overlay metrology, in accordance with one or more embodiments of the present disclosure.

FIG. 1B illustrates a schematic view of the optical sub-system with a tube lens configured to adjust a size of a field of view, in accordance with one or more embodiments of the present disclosure.

FIG. 2 illustrates an overlay target of a sample including four dies, in accordance with one or more embodiments of the present disclosure.

FIG. 3A illustrates a top view of an overlay target including a side-by-side structure combined with a see-through mark, in accordance with one or more embodiments of the present disclosure.

FIG. 3B illustrates a side-by-side mark of an overlay target with zero rotation, in accordance with one or more embodiments of the present disclosure.

FIG. 3C illustrates a side-by-side mark of an overlay target with rotational offset corresponding to a rotation, in accordance with one or more embodiments of the present disclosure.

FIG. 4A illustrates an overlay target for four dies, in accordance with one or more embodiments of the present disclosure.

FIG. 4B illustrates the overlay target of FIG. 4A with see-through structures on the dies, in accordance with one or more embodiments of the present disclosure.

FIG. 4C illustrates an overlay target for four dies with box-in-box see-through marks on the dies, in accordance with one or more embodiments of the present disclosure.

FIG. 4D illustrates an overlay target for four dies, in accordance with one or more embodiments of the present disclosure.

FIG. 5 illustrates an overlay target for four dies without die marks and with critical dimensions measured from die edges, in accordance with one or more embodiments of the present disclosure.

FIG. 6 illustrates a side view of an overlay target for a stack that is three substrates in height, in accordance with one or more embodiments of the present disclosure.

FIG. 7 illustrates a process flow diagram depicting a method of overlay metrology, in accordance with one or more embodiments of the present disclosure.

### DETAILED DESCRIPTION

The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure. Reference will now be made in detail to the subject matter disclosed, which is illustrated in the accompanying drawings.

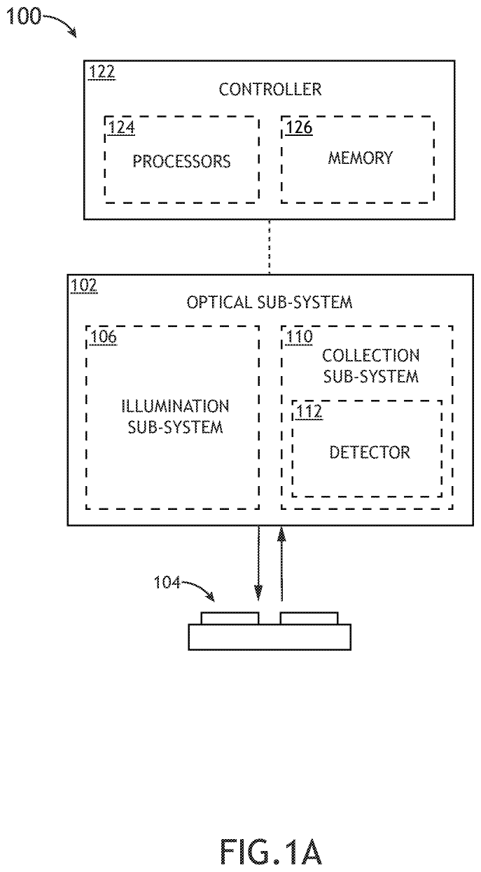

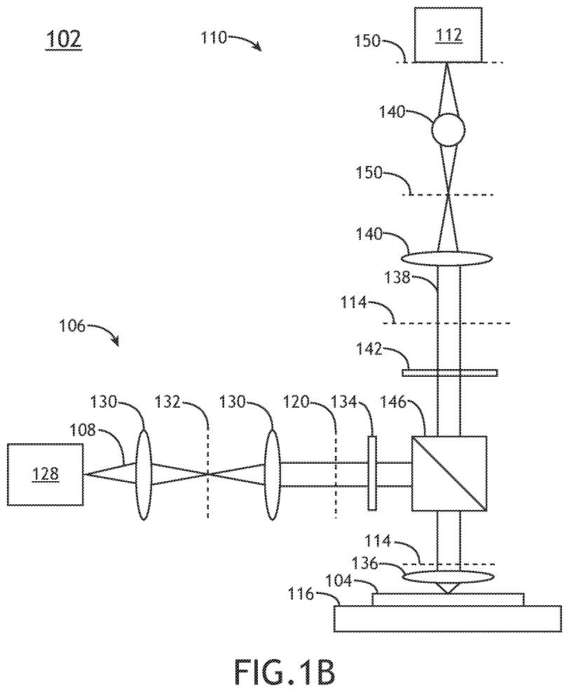

Referring to FIGS. 1A through 7, systems and methods for overlay metrology using side-by-side overlay marks are disclosed, in accordance with one or more embodiments of the present disclosure.

Embodiments of the present disclosure are directed to the utilization of side-by-side overlay marks to measure overlay in stacked die-to-wafer and/or die-to-die settings. In embodiments, multiple off-axis dies may be measured simultaneously. The overlay target marks may be positioned close enough to each other to allow for imaging of all the marks for the dies at the same time in a single field of view. Side-by-side mark methods and see-through mark methods may be combined for increased accuracy. In embodiments, rather than using die marks, die edges are used to determine overlay. In embodiments, a die mark is used for each die and compared to substrate marks between the dies to determine the overlay. For example, overlay may be determined in a single image for four dies in a two-by-two pattern with scribe lines in-between each die. Substrate marks located in the scribe lines of the carrier wafer may be shared between the dies to allow a smaller overlay target. In embodiments, a shared acquisition mark in the center of the overlay target may be used to determine and compensate for rotational error of the carrier wafer. Also, substrate marks in two directions (e.g., an X direction and a Y direction) may be shared with respective dies on opposite sides of the scribe lines.

A dynamic field of view may be adjusted using a tube lens. Changing the size of the field of view may allow for maximizing the resolution when viewing the overlay target in its entirety and for zooming in when viewing a single see-through die mark.

FIG. 1A is a conceptual view of a system 100 for overlay metrology, in accordance with one or more embodiments of the present disclosure.

In embodiments, the system 100 includes an optical sub-system 102 to perform overlay measurements on sample 104. In embodiments, the optical sub-system 102 includes an illumination sub-system 106 and a collection sub-system 110. The collection sub-system 110 may include a detector 112.

In embodiments, the system 100 includes a controller 122 communicatively coupled to the optical sub-system 102. The controller 122 may include one or more processors 124 and a memory device 126, or memory. For example, the one or more processors 124 may be configured to execute a set of program instructions maintained in the memory device 126.

FIG. 1B is a schematic view of the optical sub-system 102, in accordance with one or more embodiments of the present disclosure. The illumination sub-system 106 is configured to generate illumination in the form of one or more illumination beams 108 to illuminate the sample 104. The collection sub-system 110 is configured to collect light 138 from the illuminated sample 104. Further, the one or more illumination beams 108 may be spatially limited such that they illuminate selected portions of the sample 104. For instance, each of the one or more illumination beams 108 may be spatially limited to illuminate a particular overlay target 302. In embodiments, the collection sub-system 110 may be spatially limited to a field of view (FOV) defining the area being viewed.

In embodiments, the collection sub-system 110 includes a tube lens 140. For example, the tube lens 140 may be located within the collection pathway defined by the collection sub-system 110 and directed to the detector 112.

The detector 112 may include any detector 112 known in the art of metrology. For example, the detector 112 may include, but is not limited to, a multi-pixel detector such as a complementary metal-oxide semiconductor (CMOS) detector, a charge-coupled device (CCD) detector, or the like. The detector 112 may be located in a field plane 150 rather than a pupil plane 114 of the collection sub-system 110.

In embodiments, the optical sub-system 102 includes a translation stage 116 to move the sample 104 through a measurement field of view of the optical sub-system 102.

In embodiments, the optical sub-system 102 includes an objective lens 136 to focus the illumination beam 108 onto the sample 104. For example, the objective lens 136 may be configured to collect measurement light emanating from a sample 104 in response to the illumination beam 108 according to a metrology recipe.

The optical sub-system 102 may include one or more beamsplitters 146 for splitting light, such as for splitting the illumination beam 108.

System 100 may be configured for certain types of samples or features of a sample 104 according to a “metrology recipe.” For instance, the system 100 may be programmed to calculate overlay measurements of certain types of features according to a metrology recipe.

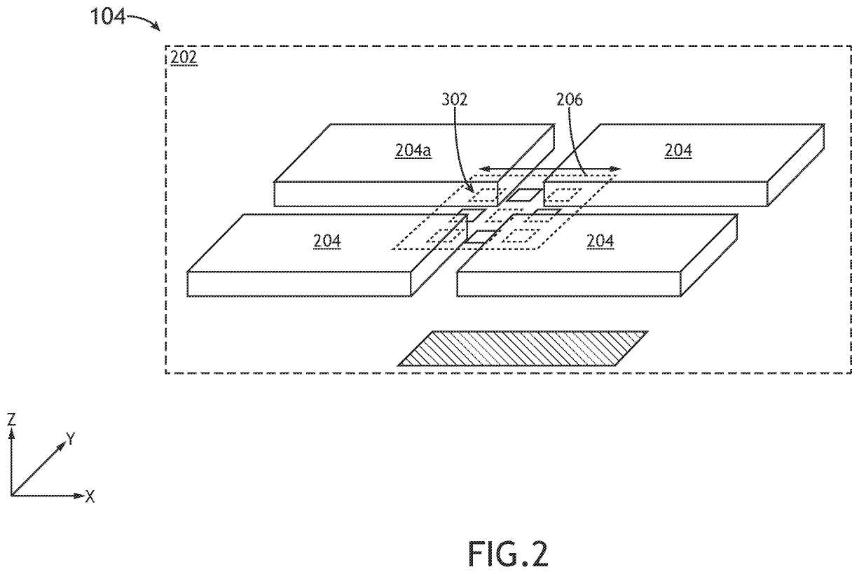

FIG. 2 illustrates an overlay target 302 of a sample 104, in accordance with one or more embodiments of the present disclosure.

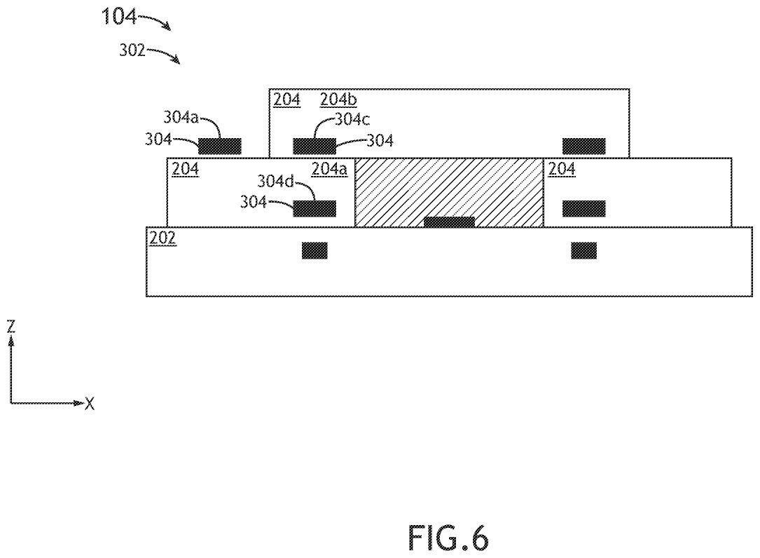

In embodiments, the sample 104 includes any number of dies. For example, the sample 104 may include one or more dies 204. For example, dies 204 may include normal dies 204 (e.g., electrically functional dies) and/or dummy dies 204 (e.g., non-electrically-functional dies). For example, the sample 104 may include die-to-wafer dies 204 as shown in FIG. 2. For instance, the substrate 202 may be a carrier wafer. By way of another example, the sample 104 may include die-to-die dies 204a, 204b as shown in FIG. 6.

In embodiments, the FOV 206 may be adjustable. It is noted that a field of view (FOV) defines what is seen and captured by the detector 112. Enlarging or reducing the size of the FOV 206 may allow for viewing the entirety of the overlay target 302 as shown or a smaller portion thereof. The field of view size may be configured to be adjusted by adjusting a tube lens 140 in a collection pathway 110 of the overlay metrology system 100. For example, the size of the FOV 206 may be adjusted (e.g., zoomed in) to view a single mark, such as a see-through die mark on a die 204. This may allow for higher resolutions when viewing a portion of the overlay target 302. For example, the controller 122 may be configured to direct an adjustment of a field of view size to be configured for viewing the see-through mark. For instance, the controller 122 may send a control signal to an actuator configured to adjust the tube lens 140 to zoom in (reduce) the size of the FOV 206. The controller 122 may further be configured to acquire a see-through mark image of the see-through mark and direct a different adjustment (e.g., zooming back out) of the field of view size to be configured for viewing an entirety of the overlay target 302.

Alternately, and/or in addition, the field of view size may be adjusted by adjusting a numerical aperture (NA) of the optical sub-system 102. For example, the NA may be adjusted in any way. For instance, the NA may be adjusted by translating components (e.g., using an actuator to move a lens), swapping out components, adjusting an iris or aperture diaphragm component, which may increase or decrease in size to allow more or less light through, thereby adjusting the numerical aperture, and/or the like.

Note that adjusting the field of view size may be configured to be performed in a different mode, such as during a mode configured for relatively low sample rate (i.e., throughput), such as for overlay targets 302 with see-through die structures. Similarly, a sample 104 may include two types of overlay targets 302, a first set including see-through die structures and a second set (without) see-through die structures. This may allow for switching between a mode that only views the entire overlay target 302, and a mode that adjusts the FOV size to view both the entire overlay target 302 and see-through die structures of a single mark for increased (spatial) resolution. The controller 122 may be configured to switch between such modes based on the overlay target 302 being imaged.

The overlay target 302 may be configured to be contained within a single field of view 206 having a width and a height no greater than 2000 microns. The overlay target 302 may be configured to be contained within a single field of view 206 having a width and a height no greater than 600 microns. The overlay target 302 may be configured to be contained within a single field of view 206 having a width and a height no greater than 400 microns.

It is to be understood, however, that the samples 104 and overlay targets 302 in FIGS. 2-6 and the associated descriptions are provided solely for illustrative purposes and should not be interpreted as limiting. Rather, the sample 104 and overlay target 302 may include any suitable design and configuration.

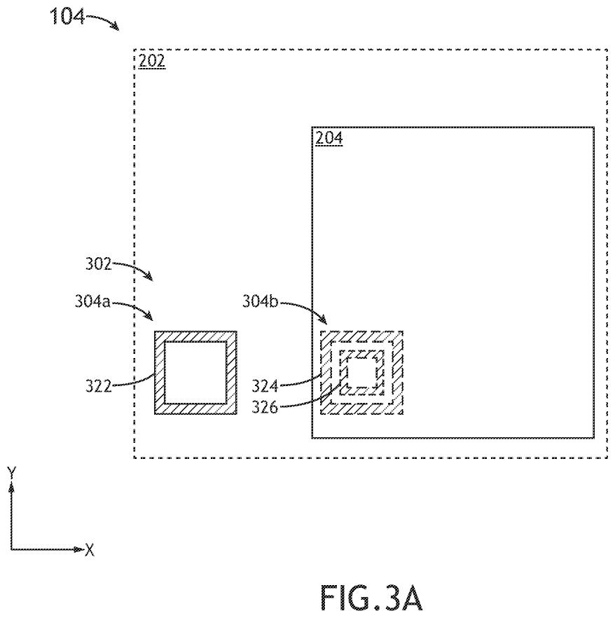

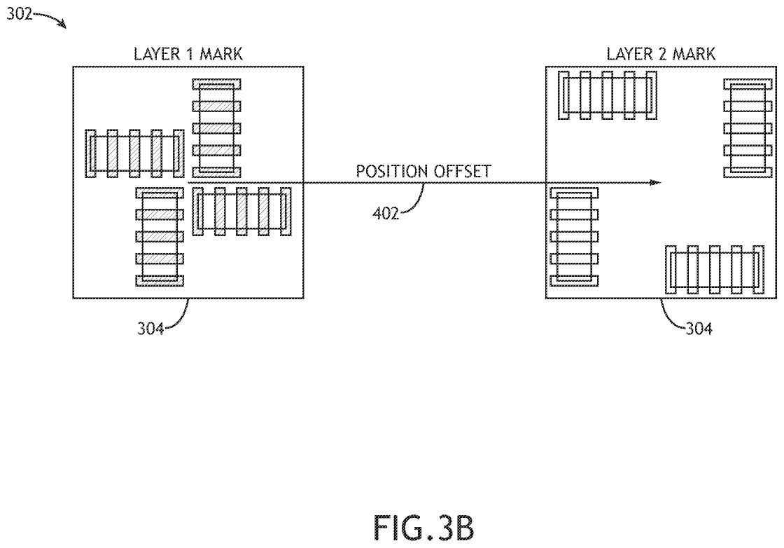

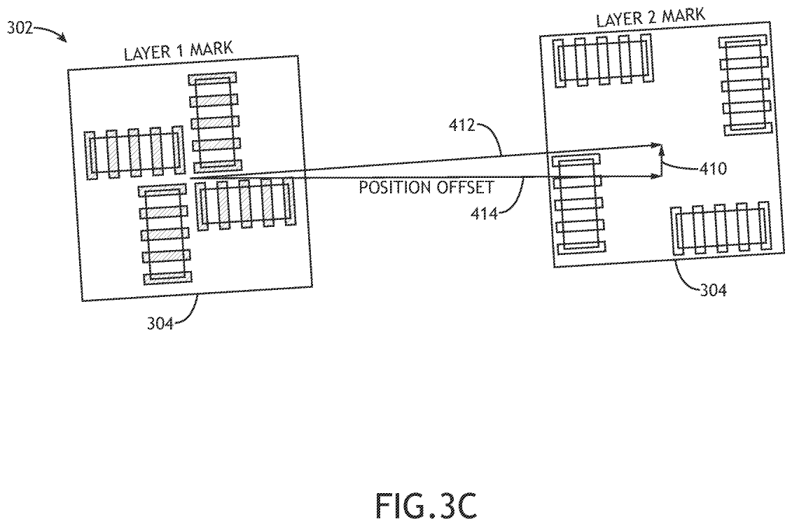

FIG. 3A is a top view of an overlay target 302 including a side-by-side structure 322 combined with a see-through mark 304b on the die 204, in accordance with one or more embodiments of the present disclosure. Combining a side-by-side structure 322 with a see-through mark 304b may allow for increased accuracy of overlay. For example, the overlay of the die 204 may be based on a comparison of a die structure 324 with both a substrate structure 326 seen ‘through’ the die structure 324, and with a substrate structure 322 seen by the ‘side’ of the die 204, such as in a scribe line. The die mark 304b may include structures configured to be used as a see-through mark, such as see-through die structures 324 within the die 204 itself and substrate structures 326 associated with a secondary substrate 202 (e.g., carrier wafer). For instance, the substrate structures 326 may be disposed in and/or on substrate 202, such as below the see-through die structures 324. The see-through mark 304b may be ‘see-through’ in the sense that the substrate structures 326 are able to be imaged from above, through the die 204 and past the see-through die structures 324. For example, the see-through die structures 324 may be above, next to, and/or the like, but not necessarily overlapping/obstructing the view of the substrate structures 326. For example, as shown, the see-through die structures 324 may include a larger rectangle above a smaller rectangle, which does not overlap the smaller rectangle. In this way, the mark 304b may include (or be) a die mark 304b and a see-through mark 304 that includes die structures 324 of the die 204 that are above substrate structures 326 of the one or more substrates 202 (e.g., secondary substrates). Secondary substrates may include any other substrate such as a carrier wafer or other die above or below the die 204.

The substrate mark 304a (which is side-by-side next to the die/see-through mark 304b) may include structures 322 configured to be used for a side-by-side overlay measurement. For example, structures 322 on the substrate 202 may be associated with a side-by-side mark 304a on the left. The structures 322 of the secondary substrate 202 may be compared to one or more of the structures 324, 326 of the die 204 to determine a side-by-side overlay.

In embodiments, determining overlay measurements includes (i) determining a side-by-side overlay between at least one of the substrate marks 304a and the die mark 304b (e.g., between structures 322 and structures 324); (ii) determining a see-through overlay based on the die mark 304b (e.g., between structures 324 and structures 326 of the die mark 304b); and (iii) determining a die overlay based on the side-by-side overlay and the see-through overlay. For instance, the die overlay may be calculated using any number of calculation methodologies. For example, the see-through overlay and side-by-side overlay may be averaged together to calculate the die overlay, which may be a single overlay measurement in a single direction of a single die 204, such as an X-direction (e.g., horizontal direction) overlay measurement of a top-right die 204. This process may be repeated for multiple directions (e.g., X and Y directions) for each die, using corresponding substrate structures 322 of substrate marks 304a associated with each direction. For instance, in the case of four dies 204, eight die overlay measurements may be determined, corresponding to two die overlay measurements for each die 204.

The determination of the die overlay may include differentially weighting the see-through overlay compared to the side-by-side overlay. For instance, the overlay measurements may be weighted according to the equation forms:

$${OVL}_{x} = a * {OVL}_{x}^{STT} + b * {OVL}_{x}^{SBS} \qquad ( Eq . 1 )$$

$${OVL}_{y} = a * {OVL}_{y}^{STT} + b * {OVL}_{y}^{SBS} \qquad ( Eq . 2 )$$

where OVLₓ and OVL_{y} are the overlay measurements in an X-direction and Y-direction, respectively; a and b are weightings; OVLₓ^{STT} is a see-through overlay in the X-direction; OVL_{y}^{STT} is a see-through overlay in the Y-direction; OVLₓ^{SBS} is a side-by-side overlay in the X-direction; and OVL_{y}^{SBS} is a side-by-side overlay in the Y-direction. The see-through structure die overlay measurement may be weighted more heavily, such as by a being a constant larger than b.

FIGS. 3B-3C illustrate structures of side-by-side marks 304 of an advance imaging metrology (AIM) overlay target 302 with zero rotation in FIG. 3B and with a rotational offset 410 in FIG. 3C, in accordance with one or more embodiments of the present disclosure. The side-by-side marks 304 may be used to determine a rotation error of a substrate 202. For example, a rotation error may occur when a carrier wafer is misaligned and rotated compared to the detector 112. The rotation error may cause error in overlay measurements. Other methodologies may take multiple move-and-measure images of the same overlay target to replace the rotation error with tool error. For example, slack in a system may contribute to rotation error and other methodologies may make repeated measurements so that the slack is averaged out. Embodiments of the present disclosure, however, may be able to measure rotation error itself using a single image of the side-by-side structures in a single field of view (FOV) of a single overlay target 302. This may eliminate the need for move-and-measure measurements, thereby increasing throughput.

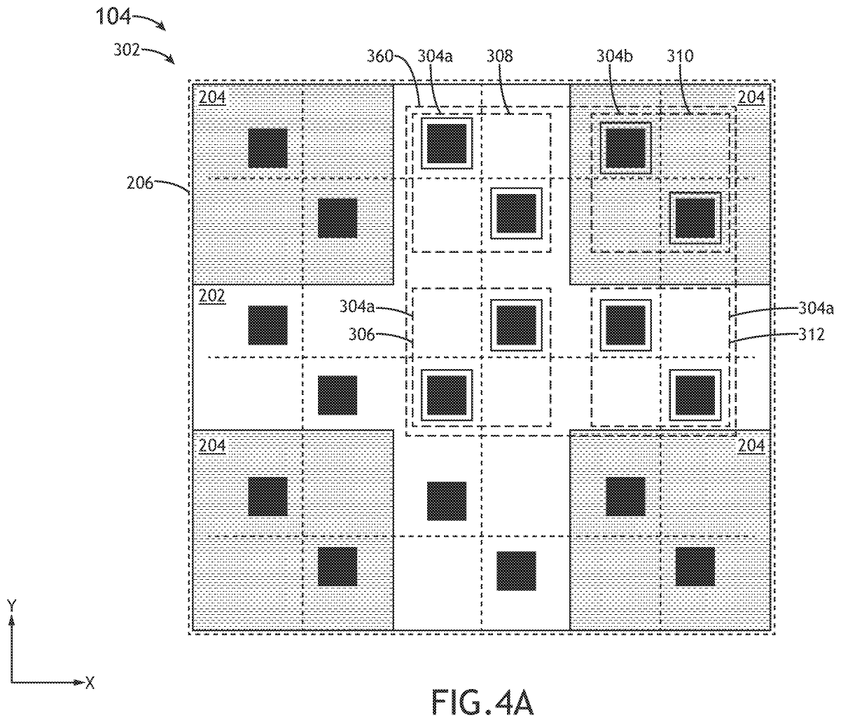

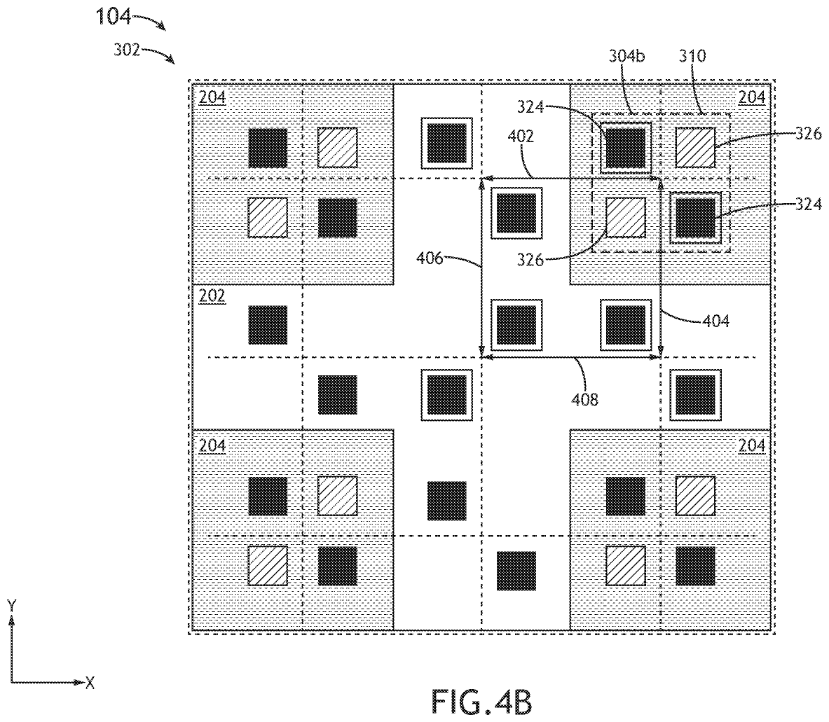

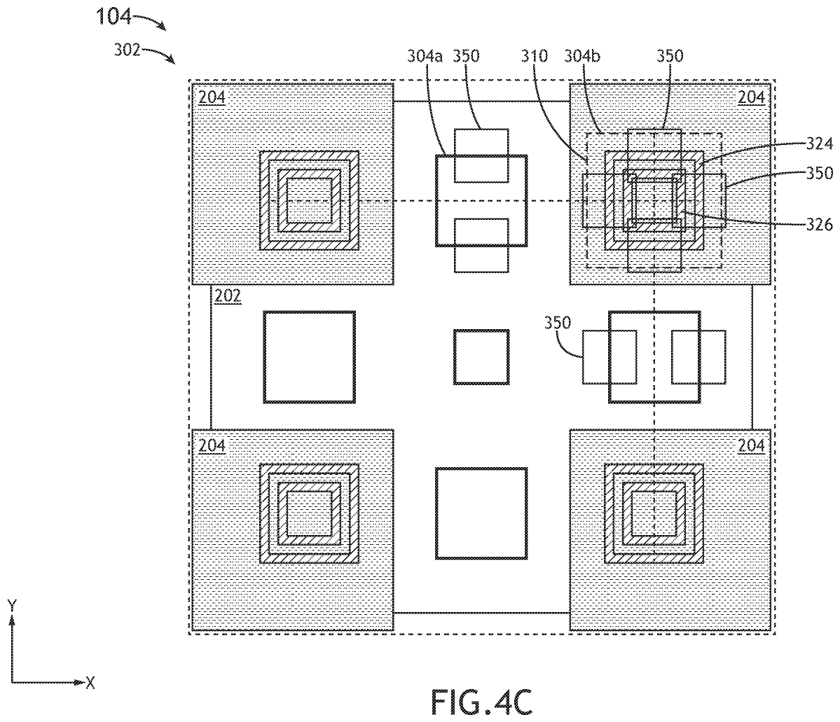

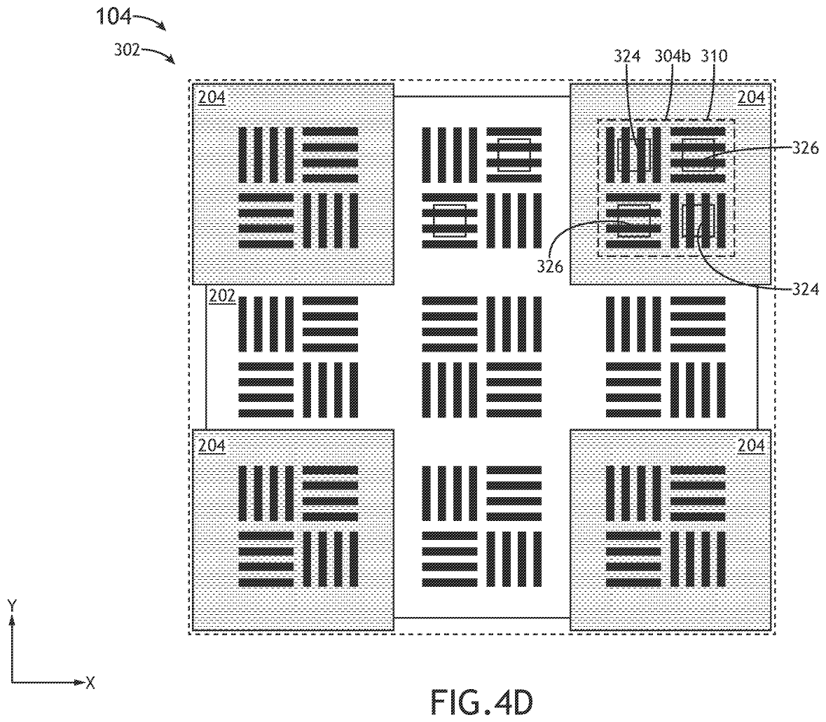

For example, a first mark 304 may be compared to a second mark 304 to determine a rotational offset 410 as shown in FIG. 3C. For instance, a first center of symmetry may be based on an acquisition mark 306 of FIG. 4A, and a second center of symmetry may be based on a different substrate mark 304a that is supposed to be horizontally or vertically aligned with the first substrate mark. For example, the rotational offset 410 may be a vertical displacement and/or amount of rotation in degrees. The rotational offset 410 may be determined based on a position (e.g., center of symmetry, corner, or the like) of an acquisition mark 306 and a position of either a first direction substrate mark 308 or a second direction substrate mark 312.

The position offset 414 may be an expected measurement between the two marks if there was no error. For instance, the position offset 414 may be based on an expected distance between the marks converted into a pixel distance. An expected location of the second mark may be determined based on the expected pixel distance (e.g., number of horizontal pixels). The expected location of the second mark may be compared to the actual location of the second mark to determine the rotational offset 410. For instance, in the case of FIG. 3C, the rotational offset 410 may be based on a number of vertical pixels between the expected location of the second mark and the actual location of the second mark. Actual distance 412 may be a measurement between the centers of the marks 304.

The overlay measurements may be based on adjustments (e.g., mathematical adjustments) configured to account for sample rotation based on the rotational offset 410. For instance, multiple rotational offsets 410 between the acquisition mark 306 and other substrate marks 308, 312 may be used to reduce noise. For example, the rotational offsets 410 may be averaged and adjusted for. An equation for angular rotation as a function of the rotational offsets 410, using a small angle approximation, may be as follows:

$$sin ( {α}_{R} ) = \frac{{offset}_{y , Horizontal}}{{offset}_{x , Horizontal}} = \frac{{offset}_{x , Vertical}}{{offset}_{y , Vertical}} \qquad ( Eq . 3 )$$

where each offset is a vector rotational offset distance 410 in the X-direction or Y-direction for a horizontal mark 308 or a vertical mark 312; and α_{R} is the angular rotation error.

For example, an error of 17.5 nanometers will be induced for marks having an angular offset of 0.01 degree and having 100 microns of separation. This amount of error may be calculated using trigonometry, look up tables, and/or the like and used to adjust the overlay measurement.

FIG. 4A is an AlMid style overlay target 302 for four dies 204, in accordance with one or more embodiments of the present disclosure.

As shown, the overlay target 302 may include measurement regions 360 for measuring overlay of each die 204. Each measurement region 360 may be used to determine a particular overlay measurement, such as die overlay of a single die 204. Any number of measurement regions 360 may be used. For example, two or more measurement regions 360 may be used. For example, four or more measurement regions 360 may be used. The measurement regions 360 may include two or more measurement regions 360 corresponding to two or more dies 204. The measurement regions 360 may include four or more measurement regions 360 corresponding to four or more dies 204.

For example, four measurement regions 360 may each overlap each other and use at least one common shared substrate mark 304a to determine overlay. For instance, an acquisition mark 306 in a center of an overlay target 302 may be shared by a two-by-two overlapping pattern of measurement regions 360 as shown. The controller 122 may determine overlay of each die 204 based on a corresponding measurement region 360. For example, a single image of the overlay target 302 may include multiple measurement regions 360 as shown. Each measurement region 360 may be cropped to analyze overlay of a respective die 204.

In embodiments, the overlay target 302 includes die marks 304b such as the die mark 310. For example, a die mark 310 may be used for each die 204.

In embodiments, the overlay target 302 includes substrate marks 304a, such as the substrate marks 306, 308, and 312. The substrate marks 304a may be characterized by being placed in a substrate region (e.g., scribe lines of the secondary substrate 202 as shown) that is unobstructed (i.e., nonoverlapping) with the dies 204.

At least one substrate mark 304a of each measurement region 360 may be commonly shared between multiple measurement regions 360. For example, the first direction substrate mark 308 and the second direction substrate mark 312 may be (or include) a common mark that is shared between two dies 204 as shown (for purposes of side-by-side overlay of adjacent dies 204). For example, acquisition mark 306, first direction substrate mark 308, and second direction substrate mark 312 may all be commonly shared.

The first direction substrate mark 308 is aligned along a first direction (e.g., X-direction) relative to a die mark 310 or multiple die marks. The second direction substrate mark 312 is aligned along a first direction (e.g., Y-direction) relative to a die mark 310 or multiple die marks. For example, the second direction may be different than the first direction, such as being orthogonal (i.e., 90 degrees) relative to each other. In this way, side-by-side overlay (and rotational offset) may be determined along two different axes (e.g., X-direction and Y-direction).

In embodiments, the overlay target 302 includes one or more first direction substrate marks 308 (e.g., two or more), one or more second direction substrate marks 312 (e.g., two or more), and an acquisition mark 306. For instance, a quantity of two of the first direction substrate marks 308 may be used, one above the other, for measuring X-direction overlay for four dies as shown.

The marks 304 may be configured in any arrangement.

For example, as shown, the overlay target 302 may include a three-by-three grid of marks 304 for four dies 204 in a two-by-two die arrangement with space (e.g., substrate scribe lines) between each die 204 for the substrate marks 306, 308, 312.

A center mark of the three by three grid of the marks 304 may include (or be) the acquisition mark 306. The acquisition mark 306 may be configured for determining a rotation offset 410 of the sample 104 as shown in FIG. 3C. Each corner of the three by three grid of the marks 304 may include a respective die mark 304b of a corresponding respective die 204.

The center mark (e.g., acquisition mark 306) may be configured to be commonly shared between four or more measurement regions 360 corresponding to the dies 204.

The acquisition mark 306 may be aligned along the first direction relative to the second direction substrate mark 312 and also aligned along the second direction relative to the first direction substrate mark 304. In other words, the acquisition mark 306 may be below mark 308 and to the left of mark 312.

The marks 304 of the overlay target 302 may be in any style. For example, the overlay target 302 may include at least one of: an AIM style target (as shown in FIG. 4D including orthogonal gratings), or a box in box style target (as shown in FIG. 4C including a box inside a box). Other styles may include, but are not limited to, a bar in bar style target.

FIG. 4B is the overlay target 302 of FIG. 4A with see-through structures 326 on the dies 204, in accordance with one or more embodiments of the present disclosure.

For example, overlay target 302 may include see-through structures 326 in the die mark 310.

First direction die distance 402 and second direction die distance 404 may be used to determine corresponding overlay measurements, such as comparing such die distances 402, 404 to expected (e.g., designed) distances. For example, the expected distances may be known based on a design of the sample 104 and may correspond to how far apart the side-by-side marks 304 would be if perfectly located with zero overlay. For example, a difference between a (known) expected distance and the first direction die distance 402 may correspond (and/or be) an overlay measurement corresponding to the die 204 in the corresponding direction (e.g., X-direction).

Acquisition mark distances 406, 408 may be used, as noted, to determine rotational offset 410 or the like.

Marks 304 may be used for on-axis determinations. For example, the diagonal axis alignment of structures 326 (e.g., a 45 degree angle) may be compared to a diagonal alignment of the acquisition mark (e.g., a 45 degree angle). Diagonal alignment of axis of structures of any of the marks 304 may be used, such as for improving the accuracy of the rotational offset 410 error and may be based on both a side by side comparison of centers of marks 304 of FIG. 3C and the diagonal axis of structures of marks 304 of FIG. 4B.

FIG. 4C is an overlay target 302 illustrating four dies 204 with box-in-box see-through marks 310 on the dies 204, in accordance with one or more embodiments of the present disclosure.

Regions of interest 350 may be used to determine one or more parameters. For example, a region of interest 350 may be used to determine a center of symmetry, a spacing between structures 324, 326, a vertical/horizontal alignment of each mark 304, and/or the like.

Marks 304 (e.g., all marks 304) may be characterized by a region of interest 350 that is positioned 180 degrees in rotational symmetry from a center of the mark 304 as shown. For example, the center of symmetry of each mark 304 may be determined based on the regions of interest 350. For example, any image processing algorithms may be configured to identify two regions of interest 350 (e.g., right side and left side of a square box). A center of two regions of interest 350 on the left and right side may be the center of symmetry in the first direction of a single mark 304. This may be done twice for regions of interest in the first direction and regions of interest in the second direction. By way of another example, the region of interest may be a filled-in square, such as shown by structures 324 in FIG. 4B, and the center may be identified by calculating the center of the square (e.g., center of the outer edges of the square).

FIG. 4D is an overlay target 302 for four dies 204, in accordance with one or more embodiments of the present disclosure.

Note that the marks of FIG. 4D include grating structures, such as periodic gratings. Each set of gratings may correspond to a region of interest 350.

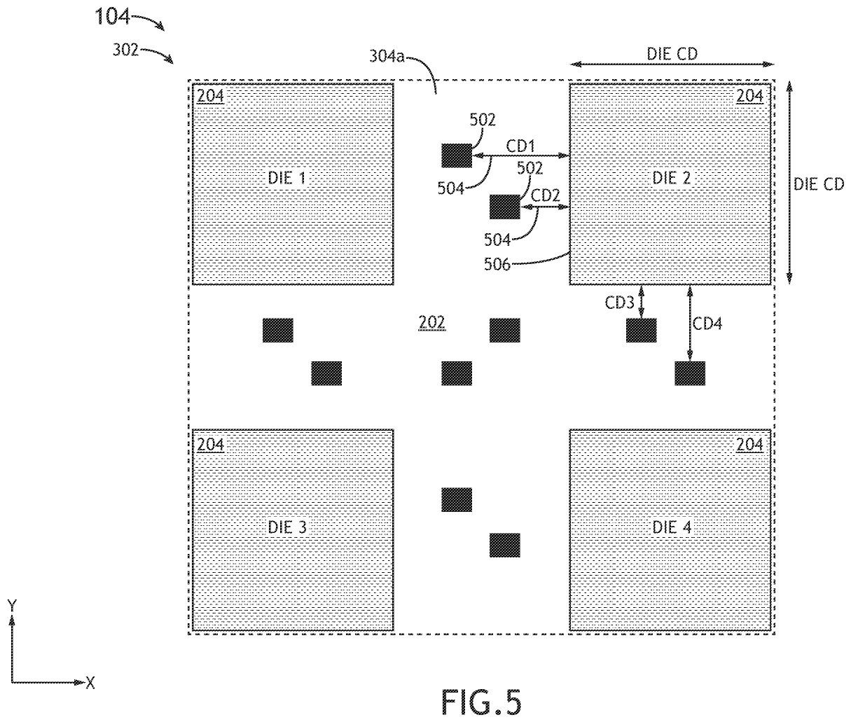

FIG. 5 is an overlay target 302 for four dies 204 without die marks and with critical dimensions 504 measured from die edges 506, in accordance with one or more embodiments of the present disclosure.

The optical sub-system 102 may be configured for bright field metrology, such as being in a bright field configuration and using the bright field configuration to determine critical dimensions 504 of structures 502 of an overlay target 302. For example, the die 204 in FIG. 5 does not have any die marks. The overlay measurements, including die overlay in each direction for each die 204, may be determined based on one or more critical dimensions 504. For example, a die overlay in a first direction may be based on a first critical dimension 504 (CD1), (CD2) based on first structures 502 of the first direction substrate mark 304 and a first die edge 506. Likewise, for the second direction, a second critical dimension (CD3), (CD4) may be determined based on second structures of the second direction substrate mark and a second die adjacent to the first die edge 506. For instance, the first critical dimensions 504 may be compared to expected critical dimensions based on a known design of the sample 104, where a difference corresponds to an overlay misalignment.

FIG. 6 is a side view of an overlay target 302 for a stack that is three substrates (e.g., carrier substrate 202, first substrate 204a, second substrate 204b) in height, in accordance with one or more embodiments of the present disclosure.

As shown, the methodology herein may be applied to die-to-die (D2D) and/or die-to-wafer (D2W) samples 104. For example, the secondary substrate may be a base substrate (e.g., carrier wafer) and/or one or more dies (stacked dies in a D2D configuration). In a D2D scenario, the substrate marks may be located on a secondary die 204a below the die 204b. A second see-through mark structure 304d may be located below a first see-through mark structure 304c. In this way, three or more stacked substrates may be used with methodologies herein.

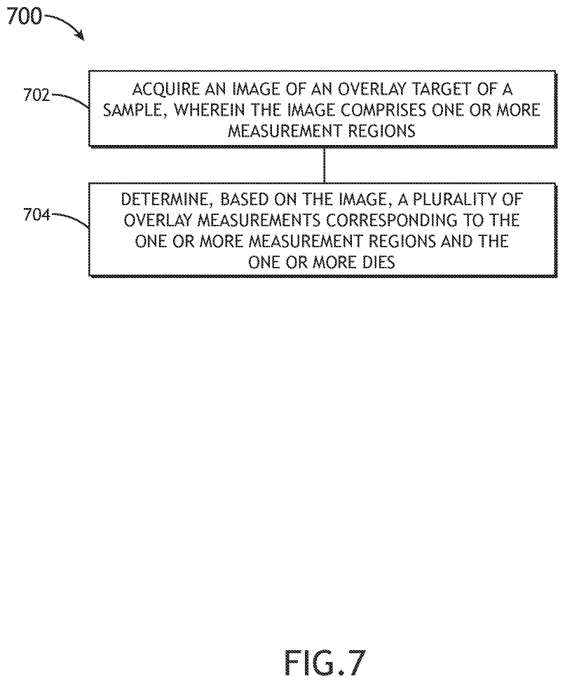

FIG. 7 illustrates a process flow diagram of a method 700 for overlay metrology, in accordance with one or more embodiments of the present disclosure. It is noted that the embodiments and enabling technologies described previously herein in the context of the system 100 should be interpreted to extend to the method 700. It is further noted herein that the steps of method 700 may be implemented all or in part by system 100. It is further recognized, however, that the method 700 is not limited to the system 100 in that additional or alternative system-level embodiments may carry out all or part of the steps of method 700.

In step 702, an image of an overlay target 302 of a sample 104 is acquire, wherein the image includes one or more measurement regions 360. For example, optical sub-system 102 may capture/acquire/receive an image of overlay target 302 using detector 112.

In step 704, based on the image of step 702, overlay measurements corresponding to the one or more measurement regions and the one or more dies are determined. For example, the overlay measurements may be determined in the first direction and the second direction for each die 204. For instance, one or more methodologies herein may be used, which may include, but are not necessarily limited to, compact configuration of a single image of overlapping measurement regions corresponding to respective dies 204, shared marks 304, weighting of overlays of combined side-by-side/see-through marks, or determining the overlay based on adjustments for rotational offset error.

In another step (not shown), one or more processes of a manufacturing of the sample 104 are controlled based on the overlay measurements. This may involve adjusting the parameters of the process (such as die location placement parameters, light frequency, intensity, or processing time) in order to minimize the overlay. The adjustments may be made manually by an operator, or automatically by a control system in response to the overlay measurement. For example, if the overlay measurement is greater than a predetermined threshold, then the process parameter(s) might be adjusted to reduce the overlay. Conversely, if the overlay measurement is less than the threshold, then the process parameter(s) might be left unchanged, or possibly adjusted to decrease the overlay slightly in order to keep it within an optimal range. Such processes could include semiconductor manufacturing, photolithography, and many others.

Referring again to FIGS. 1A-1B, various components are described in greater detail in accordance with one or more embodiments of the present disclosure.

The one or more processors 124 of the controller 122 may include any processor or processing element known in the art. For the purposes of the present disclosure, the term “processor” or “processing element” may be broadly defined to encompass any device having one or more processing or logic elements (e.g., one or more micro-processor devices, one or more application specific integrated circuit (ASIC) devices, one or more field programmable gate arrays (FPGAs), or one or more digital signal processors (DSPs)). In this sense, the one or more processors 124 may include any device configured to execute algorithms and/or instructions (e.g., program instructions stored in memory). In embodiments, the one or more processors 124 may be embodied as a desktop computer, mainframe computer system, workstation, image computer, parallel processor, networked computer, or any other computer system configured to execute a program configured to operate or operate in conjunction with the system 100, as described throughout the present disclosure. Moreover, different subsystems of the system 100 may include a processor or logic elements suitable for carrying out at least a portion of the steps described in the present disclosure. Therefore, the above description should not be interpreted as a limitation on the embodiments of the present disclosure but merely as an illustration. Further, the steps described throughout the present disclosure may be carried out by a single controller or, alternatively, multiple controllers. Additionally, the controller 122 may include one or more controllers housed in a common housing or within multiple housings. In this way, any controller or combination of controllers may be separately packaged as a module suitable for integration into system 100. Further, the controller 122 may analyze or otherwise process data received from the one or more detectors 112 and feed the data to additional components within the system 100 or external to the system 100.

Further, the memory device 126 may include any storage medium known in the art suitable for storing program instructions executable by the associated one or more processors 124. For example, the memory device 126 may include a non-transitory memory medium. As an additional example, the memory device 126 may include, but is not limited to, a read-only memory, a random-access memory, a magnetic or optical memory device (e.g., disk), a magnetic tape, a solid-state drive and the like. It is further noted that memory device 126 may be housed in a common controller housing with the one or more processors 124.

In this regard, the controller 122 may execute any of various processing steps associated with overlay metrology. For example, the controller 122 may be configured to generate control signals to direct or otherwise control the optical sub-system 102, or any components thereof. For instance, the controller 122 may be configured to receive signals corresponding to the images from the one or more detectors 112. By way of another example, the controller 122 may generate correctables for one or more additional fabrication tools as feedback and/or feed-forward control of the one or more additional fabrication tools based on overlay measurements from the optical sub-system 102.

Further, the controller 122 may calibrate or otherwise modify the overlay measurement based on known, assumed, or measured features of the sample 104 that may also impact the images such as, but not limited to, sidewall angles or other sample asymmetries.

Referring again to FIG. 1B, various components of the optical sub-system 102 are described in greater detail in accordance with one or more embodiments of the present disclosure.

In embodiments, the illumination sub-system 106 includes an illumination source 128 configured to generate at least one illumination beam 108. The illumination from the illumination source 128 may include one or more selected wavelengths of light including, but not limited to, ultraviolet (UV) radiation, visible radiation, or infrared (IR) radiation.

The illumination source 128 may include any type of illumination source suitable for providing at least one illumination beam 108. In embodiments, the illumination source 128 is a laser source. For example, the illumination source 128 may include, but is not limited to, one or more narrowband laser sources, a broadband laser source, a supercontinuum laser source, a white light laser source, or the like. In this regard, the illumination source 128 may provide an illumination beam 108 having high coherence (e.g., high spatial coherence and/or temporal coherence). In embodiments, the illumination source 128 includes a laser-sustained plasma (LSP) source. For example, the illumination source 128 may include, but is not limited to, a LSP lamp, a LSP bulb, or a LSP chamber suitable for containing one or more elements that, when excited by a laser source into a plasma state, may emit broadband illumination.

In embodiments, the illumination sub-system 106 includes one or more optical components suitable for modifying and/or conditioning the illumination beam 108 as well as directing the illumination beam 108 to the sample 104. For example, the illumination sub-system 106 may include one or more illumination lenses 130 (e.g., to collimate the illumination beam 108, to relay an illumination pupil plane 120 and/or an illumination field plane 132, or the like). In embodiments, the illumination sub-system 106 includes one or more illumination control optics 134 to shape or otherwise control the illumination beam 108. For example, the illumination control optics 134 may include, but are not limited to, one or more field stops, one or more pupil stops, one or more polarizers, one or more filters, one or more beam splitters, one or more diffusers, one or more homogenizers, one or more apodizers, one or more beam shapers, or one or more mirrors (e.g., static mirrors, translatable mirrors, scanning mirrors, or the like).

The collection sub-system 110 may include one or more optical elements suitable for modifying and/or conditioning the collected light 138 from the sample 104. In embodiments, the collection sub-system 110 includes one or more collection lenses 140 (e.g., a tube lens 140). In embodiments, the collection sub-system 110 includes one or more collection control optics 142 to shape or otherwise control the collected light 138. For example, the collection control optics 142 may include, but are not limited to, one or more field stops, one or more pupil stops, one or more polarizers, one or more filters, one or more beam splitters, one or more diffusers, one or more homogenizers, one or more apodizers, one or more beam shapers, or one or more mirrors (e.g., static mirrors, translatable mirrors, scanning mirrors, or the like). In another example, the collection sub-system 110 may include one or more collection field planes 150.

Referring again to FIG. 1A, it is noted herein that the one or more components of system 100 may be communicatively coupled to the various other components of system 100 in any manner known in the art. For example, the one or more processors 124 may be communicatively coupled to each other and other components via a wireline (e.g., copper wire, fiber optic cable, and the like) or wireless connection (e.g., RF coupling, IR coupling, WiMax, Bluetooth, 3G, 4G, 4G LTE, 5G, and the like). By way of another example, the controller 122 may be communicatively coupled to one or more components of optical sub-system 102 via any wireline or wireless connection known in the art.

In embodiments, the one or more processors 124 may include any one or more processing elements known in the art. In this sense, the one or more processors 124 may include any microprocessor-type device configured to execute software algorithms and/or instructions. In embodiments, the one or more processors 124 may consist of a desktop computer, mainframe computer system, workstation, image computer, parallel processor, or other computer system (e.g., networked computer) configured to execute a program configured to operate the system 100, as described throughout the present disclosure. It should be recognized that the steps described throughout the present disclosure may be carried out by a single computer system or, alternatively, multiple computer systems. Furthermore, it should be recognized that the steps described throughout the present disclosure may be carried out on any one or more of the one or more processors 124. In general, the term “processor” may be broadly defined to encompass any device having one or more processing elements, which execute program instructions from memory 126. Moreover, different subsystems of the system 100 may include processor or logic elements suitable for carrying out at least a portion of the steps described throughout the present disclosure. Therefore, the above description should not be interpreted as a limitation on the present disclosure but merely an illustration.

One skilled in the art will recognize that the herein described components (e.g., operations), devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components (e.g., operations), devices, and objects should not be taken as limiting.

Those having skill in the art will appreciate that there are various vehicles by which processes and/or systems and/or other technologies described herein can be effected (e.g., hardware, software, and/or firmware), and that the preferred vehicle will vary with the context in which the processes and/or systems and/or other technologies are deployed. For example, if an implementer determines that speed and accuracy are paramount, the implementer may opt for a mainly hardware and/or firmware vehicle; alternatively, if flexibility is paramount, the implementer may opt for a mainly software implementation; or, yet again alternatively, the implementer may opt for some combination of hardware, software, and/or firmware. Hence, there are several possible vehicles by which the processes and/or devices and/or other technologies described herein may be effected, none of which is inherently superior to the other in that any vehicle to be utilized is a choice dependent upon the context in which the vehicle will be deployed and the specific concerns (e.g., speed, flexibility, or predictability) of the implementer, any of which may vary.

The previous description is presented to enable one of ordinary skill in the art to make and use the invention as provided in the context of a particular application and its requirements. Various modifications to the described embodiments will be apparent to those with skill in the art, and the general principles defined herein may be applied to other embodiments. Therefore, the present invention is not intended to be limited to the particular embodiments shown and described, but is to be accorded the widest scope consistent with the principles and novel features herein disclosed.

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

All of the methods described herein may include storing results of one or more steps of the method embodiments in memory. The results may include any of the results described herein and may be stored in any manner known in the art. The memory may include any memory described herein or any other suitable storage medium known in the art. After the results have been stored, the results can be accessed in the memory and used by any of the method or system embodiments described herein, formatted for display to a user, used by another software module, method, or system, and the like. Furthermore, the results may be stored “permanently,” “semi-permanently,” temporarily,” or for some period of time. For example, the memory may be random access memory (RAM), and the results may not necessarily persist indefinitely in the memory.

It is further contemplated that each of the embodiments of the method described above may include any other step(s) of any other method(s) described herein. In addition, each of the embodiments of the method described above may be performed by any of the systems described herein.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Specific examples of couplable include but are not limited to physically mateable and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

We claim:

1. An overlay target, the overlay target comprising:
one or more measurement regions, each measurement region corresponding to a die, wherein each measurement region comprises:
one or more die marks located on one or more dies; and
substrate marks located on one or more substrates, wherein the substrate marks are unobstructed by the one or more dies, wherein the substrate marks comprise:
a first direction substrate mark aligned along a first direction relative to a die mark; and
a second direction substrate mark aligned along a second direction relative to the die mark, wherein the second direction is different than the first direction.

2. The overlay target of claim 1, wherein the substrate marks of each measurement region further comprise an acquisition mark, wherein the acquisition mark is aligned along the first direction relative to the second direction substrate mark, and aligned along the second direction relative to the first direction substrate mark.

3. The overlay target of claim 2, wherein the one or more measurement regions comprises two or more measurement regions corresponding to two or more dies, wherein at least one substrate mark of each measurement region is commonly shared between multiple measurement regions.

4. The overlay target of claim 3, wherein the two or more measurement regions comprises four or more measurement regions corresponding to four or more dies.

5. The overlay target of claim 4, wherein the at least one substrate mark of each measurement region that is commonly shared between multiple measurement regions comprises:
the acquisition mark;
the first direction substrate mark; and
the second direction substrate mark.

6. The overlay target of claim 5, wherein the overlay target comprises a three by three grid of marks configured for four dies in a two by two arrangement with space between each die for the substrate marks, wherein a center mark of the three by three grid of the marks comprises the acquisition mark and wherein the center mark is configured to be commonly shared between the four or more measurement regions corresponding to the four dies, wherein each corner of the three by three grid of the marks comprises a respective die mark of a respective die of the four or more dies.

7. The overlay target of claim 1, wherein the overlay target is configured to be contained within a single field of view having a width and a height no greater than 2000 microns.

8. The overlay target of claim 1, wherein the overlay target is configured to be contained within a single field of view having a width no greater than 600 microns.

9. The overlay target of claim 1, wherein the die mark of the die comprises a see-through mark comprising die structures of the die that are above substrate structures of the one or more substrates.

10. The overlay target of claim 1, wherein the overlay target comprises at least one of: an advance imaging metrology (AIM) style target, or a box in box style target.

11. An overlay metrology system comprising:
a detector; and
a controller communicatively coupled to the detector and including one or more processors configured to execute program instructions causing the one or more processors to:
acquire an image of an overlay target of a sample, wherein the sample comprises one or more dies corresponding to one or more substrates, wherein the overlay target comprises: one or more measurement regions, each measurement region corresponding to a die, wherein each measurement region comprises: one or more die marks located on one or more dies; and substrate marks located on the one or more substrates, wherein the substrate marks are unobstructed by the one or more dies, wherein the substrate marks comprise: a first direction substrate mark aligned along a first direction relative to a die mark; and a second direction substrate mark aligned along a second direction relative to the die mark, wherein the second direction is different than the first direction, and
determine, based on the image, a plurality of overlay measurements corresponding to the one or more measurement regions and the one or more dies.

12. The overlay metrology system of claim 11, wherein the determining of the plurality of overlay measurements comprises:
determining a rotational offset based on a position of an acquisition mark and a position of one of the first direction substrate mark or the second direction substrate mark,
wherein the plurality of overlay measurements are based on adjustments configured to account for sample rotational based on the rotational offset.

13. The overlay metrology system of claim 12, wherein the die mark comprises a see-through mark comprising die structures of the die that are above substrate structures of the one or more substrates,
wherein the determining of the plurality of overlay measurements comprises:
determining a side-by-side overlay between at least one of the substrate marks and the die mark;
determining a see-through overlay based on the one or more die marks; and
determining a die overlay based on the side-by-side overlay and the see-through overlay.

14. The overlay metrology system of claim 13, wherein the determining the die overlay based on the side-by-side overlay and the see-through overlay comprises:
differentially weighting the see-through overlay compared to the side-by-side overlay when determining the die overlay.

15. The overlay metrology system of claim 13, wherein the controller is further configured to:
direct an adjustment of a field of view size of the overlay metrology system to be configured for viewing the see-through mark;
acquire a see-through mark image of the see-through mark; and
direct a different adjustment of the field of view size to be configured for viewing an entirety of the overlay target.

16. The overlay metrology system of claim 15, wherein the field of view size of the overlay metrology system is configured to be adjusted by adjusting a tube lens in a collection pathway of the overlay metrology system.

17. An overlay metrology system comprising:
an optical subsystem; and
a controller including one or more processors configured to execute program instructions causing the one or more processors to:
acquire an image emanating from an overlay target of a sample, wherein the image comprises one or more measurement regions,
wherein the sample comprises one or more dies corresponding to one or more substrates,
wherein the overlay target comprises:
the one or more measurement regions, each measurement region corresponding to a die, wherein each measurement region comprises:
substrate marks located on a substrate, wherein the substrate marks are unobstructed by the one or more dies, wherein the substrate marks comprise:
a first direction substrate mark offset along a first direction relative to a first die edge; and
a second direction substrate mark offset along a second direction relative to a second die edge, wherein the second direction is different than the first direction, and
determine, based on the image, a plurality of overlay measurements corresponding to the one or more measurement regions and the one or more dies.

18. The overlay metrology system of claim 17, wherein an optical sub-system is configured for bright field critical dimensions of structures of an overlay target.

19. The overlay metrology system of claim 17, wherein the determining of the plurality of overlay measurements comprises:
determining a first critical dimension based on first structures of the first direction substrate mark and the first die edge; and
determining a second critical dimension based on second structures of the second direction substrate mark and the second die edge,
wherein the plurality of overlay measurements are based on the first critical dimension and the second critical dimension.

20. A method comprising:
acquiring an image of an overlay target of a sample, wherein the image comprises one or more measurement regions,
wherein the sample comprises a one or more dies corresponding to one or more substrates,
wherein the overlay target comprises:
the one or more measurement regions, each measurement region corresponding to a die, wherein each measurement region comprises:
one or more die marks located on one or more dies; and
substrate marks located on the one or more substrates, wherein the substrate marks are unobstructed by the one or more dies, wherein the substrate marks comprise:
a first direction substrate mark aligned along a first direction relative to a die mark; and
a second direction substrate mark aligned along a second direction relative to the die mark, wherein the second direction is different than the first direction, and
determining, based on the image, a plurality of overlay measurements corresponding to the one or more measurement regions and the one or more dies.

21. The method of claim 20, wherein the determining of the plurality of overlay measurements comprises:
determining a rotational offset based on a position of an acquisition mark and a position of one of the first direction substrate mark or the second direction substrate mark,
wherein the plurality of overlay measurements are based on adjustments configured to account for sample rotational based on the rotational offset.

22. The method of claim 21, wherein the die mark comprises a see-through mark comprising die structures of the die that are above substrate structures of the one or more substrates,
wherein the determining of the plurality of overlay measurements comprises:
determining a side-by-side overlay between at least one of the substrate marks and the die mark;
determining a see-through overlay based on the one or more die marks; and
determining a die overlay based on the side-by-side overlay and the see-through overlay.

23. The method of claim 22, wherein the determining the die overlay based on the side-by-side overlay and the see-through overlay comprises:
differentially weighting the see-through overlay compared to the side-by-side overlay when determining the die overlay.

24. The method of claim 22 further comprising:
directing an adjustment of a field of view size configured for viewing the see-through mark;
receiving a see-through mark image of the see-through mark; and
directing a different adjustment of the field of view size to be configured for viewing an entirety of the overlay target.

25. The method of claim 24, wherein the field of view size is configured to be adjusted by adjusting a tube lens in a collection pathway of an overlay metrology system.
